(19) United States
(12) Patent Application Publication
(10) Pub. No.: US 2026/0248022 A1
(43) Pub. Date: Aug. 20, 2026

(54) METHOD OF PROCESSING SUBSTRATE, METHOD OF MANUFACTURING SEMICONDUCTOR DEVICE, SUBSTRATE PROCESSING APPARATUS, SEMICONDUCTOR DEVICE, AND RECORDING MEDIUM

(71) Applicant: Kokusai Electric Corporation, Tokyo (JP)

(72) Inventors: Hiroshi ASHIHARA, Tokyo (JP); Tsuyoshi ISHIKAWA, Tokyo (JP); Shuntaro MACHIDA, Tokyo (JP); Naofumi OHASHI, Toyama-shi (JP)

(73) Assignee: Kokusai Electric Corporation, Tokyo (JP)

(21) Appl. No.: 19/647,186

(22) Filed: Apr. 14, 2026

Related U.S. Application Data
(63) Continuation of application No. PCT/JP2024/012386, filed on Mar. 27, 2024.

(51) Int. Cl. H10W 74/01; H10W 74/15; H10W 90/00

(52) U.S. Cl. CPC H10W 74/012; H10W 74/15; H10W 90/724

(57) ABSTRACT

A technique includes preparing a substrate bonded to a semiconductor chip by micro bumps formed on at least one of a first surface of the substrate, which is a bonding surface side that bonds with the semiconductor chip, and a second surface of the semiconductor chip, which is a bonding surface side that bonds with the substrate; and forming, on the first surface and the second surface, a liner film including an insulating film so as to form a surface on which an underfill film can be formed between the substrate and the semiconductor chip.

### DESCRIPTION

### CROSS-REFERENCE TO RELATED APPLICATION

This application is a Bypass Continuation Application of PCT International Application No. PCT/JP2024/012386, filed on March 27, 2024, the disclosure of which is incorporated herein in its entirety by reference.

### TECHNICAL FIELD

The present disclosure relates to a method of processing a substrate, a method of manufacturing a semiconductor device, a semiconductor device, a substrate processing apparatus, and a recording medium.

### BACKGROUND

In the related art, as one step in a process of manufacturing a semiconductor device, a processing gas may be supplied to a substrate within a processing vessel to form a film on the substrate.

In one step of a process of manufacturing a semiconductor device in which an underfill material is filled between a substrate and a semiconductor chip, voids may occur.

### SUMMARY

Some embodiments of the present disclosure provide a technique capable of suppressing the occurrence of voids when an underfill material is filled between a substrate and a semiconductor chip.

According to one embodiment of the present disclosure, there is provided a technique including preparing a substrate bonded to a semiconductor chip by micro bumps formed on at least one of a first surface of the substrate, which is a bonding surface side that bonds with the semiconductor chip, and a second surface of the semiconductor chip, which is a bonding surface side that bonds with the substrate; and forming, on the first surface and the second surface, a liner film including an insulating film so as to form a surface on which an underfill film can be formed between the substrate and the semiconductor chip.

### BRIEF DESCRIPTION OF DRAWINGS

The accompanying drawings, which are incorporated in and constitute a part of the specification, illustrate embodiments of the present disclosure.

FIG. 1A is a schematic view illustrating one step of a process of manufacturing a semiconductor device according to embodiments of the present disclosure.

FIG. 1B is a schematic view illustrating one step of a process of manufacturing a semiconductor device according to embodiments of the present disclosure.

FIG. 1C is a schematic view illustrating one step of a process of manufacturing a semiconductor device according to embodiments of the present disclosure.

FIG. 2 is a schematic configuration diagram of a substrate processing apparatus used in a liner film formation step according to embodiments of the present disclosure.

FIG. 3 is a block diagram for explaining a control configuration of the substrate processing apparatus used in the liner film formation step according to embodiments of the present disclosure.

FIG. 4 is a flowchart illustrating an example of the liner film formation step according to embodiments of the present disclosure.

FIG. 5A is a schematic view illustrating one step of a process of manufacturing a semiconductor device according to a second embodiment of the present disclosure.

FIG. 5B is a schematic view illustrating one step of a process of manufacturing a semiconductor device according to the second embodiment of the present disclosure.

FIG. 6A is a schematic view illustrating one step of a process of manufacturing a semiconductor device according to a third embodiment of the present disclosure.

FIG. 6B is a schematic view illustrating one step of a process of manufacturing a semiconductor device according to the third embodiment of the present disclosure.

FIG. 7A is a schematic view illustrating one step of a process of manufacturing a semiconductor device according to a fifth embodiment of the present disclosure.

FIG. 7B is a schematic view illustrating one step of a process of manufacturing a semiconductor device according to the fifth embodiment of the present disclosure.

FIG. 7C is a schematic view illustrating one step of a process of manufacturing a semiconductor device according to the fifth embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to unnecessarily obscure aspects of the various embodiments.

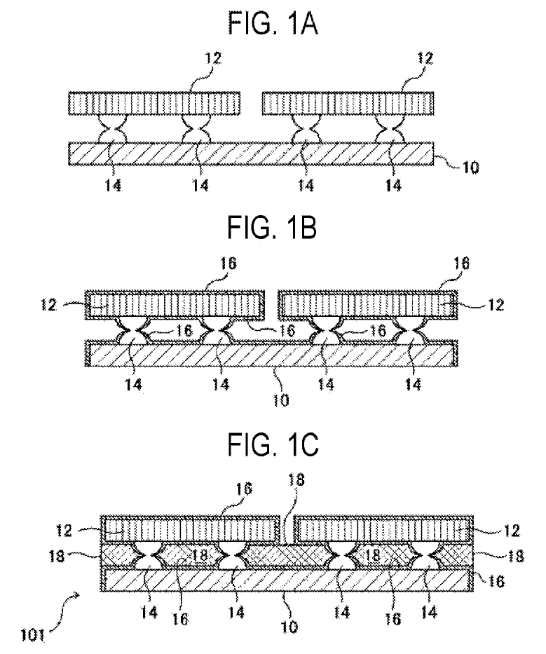

Hereinafter, one embodiment of the present disclosure will be described mainly with reference to FIGS. 1A to 1C, FIGS. 2, 3, and 4, FIGS. 5A and 5B, FIGS. 6A and 6B, and FIGS. 7A to 7C. It should be noted that all of the drawings used in the following description are schematic, and the dimensional relationships among the elements, the ratios of the elements, and the like shown in the drawings do not necessarily correspond to actual ones. Further, the dimensional relationships among the elements, the ratios of the elements, and the like do not necessarily correspond among the plurality of drawings. Substantially the same elements among the plurality of figures are denoted by the same reference numerals; the description of each element is given in the figure in which the element first appears, and the description thereof is omitted in the subsequent figures unless particularly necessary. Further, the present disclosure is not limited to the embodiments to be described below, and may be implemented with appropriate modifications within the scope of the present disclosure.

1. Process of Manufacturing Semiconductor Device

First, one step of a process of manufacturing a semiconductor device 101 according to one embodiment of the present disclosure will be described in detail with reference to FIGS. 1A to 1C.

### Liner Film Formation Step, Step S1

AS ILLUSTRATED IN FIG. 1A, A SUBSTRATE 10 AND A SEMICONDUCTOR CHIP 12 ARE BONDED BY MICRO BUMPS 14 FORMED RESPECTIVELY ON A SURFACE OF THE SUBSTRATE 10, WHICH IS A BONDING SURFACE SIDE THAT BONDS WITH THE SEMICONDUCTOR CHIP 12 (HEREINAFTER ALSO REFERRED TO AS A "FIRST SURFACE"), AND ON A SURFACE OF THE SEMICONDUCTOR CHIP 12, WHICH IS A BONDING SURFACE SIDE THAT BONDS WITH THE SUBSTRATE 10 (HEREINAFTER ALSO REFERRED TO AS A "SECOND SURFACE"). AS ILLUSTRATED IN FIG. 1B, AT LEAST ONE LAYER OF AN INSULATING FILM 16 IS CONFORMALLY FORMED AS A LINER FILM ON AT LEAST THE FIRST SURFACE, THE SECOND SURFACE, AND SURFACES OF THE MICRO BUMPS 14 OF THE SUBSTRATE 10 AND THE SEMICONDUCTOR CHIP 12 THUS BONDED. ALTHOUGH NOT ILLUSTRATED, MULTIPLE TYPES OF FILMS SUCH AS INSULATING FILMS AND METAL FILMS ARE FORMED ON THE SURFACE OF THE SUBSTRATE 10 AND ON THE SURFACE OF THE SEMICONDUCTOR CHIP 12, AND ELEMENTS AND THE LIKE ARE FURTHER PROVIDED THEREON, SO THAT THE SURFACE MATERIALS DIFFER FROM EACH OTHER. THE MICRO BUMPS 14 ARE, FOR EXAMPLE, A TIN (SN)-CONTAINING ALLOY, A SILVER (AG)-CONTAINING ALLOY, AN AGSN ALLOY, OR THE LIKE. HERE, THE SURFACE OF THE SUBSTRATE 10, WHICH IS THE BONDING SURFACE SIDE THAT BONDS WITH THE SEMICONDUCTOR CHIP 12, IS ALSO REFERRED TO AS THE FIRST SURFACE. THE FIRST SURFACE INCLUDES AT LEAST THE SURFACE OF THE SUBSTRATE, BUT IS NOT LIMITED THERETO, AND MAY INCLUDE AT LEAST ONE SURFACE AMONG SURFACES OF VARIOUS FILMS (E.G., AN INSULATING FILM, A METAL FILM, ETC.) AND ELEMENTS PROVIDED ON THE SUBSTRATE SURFACE. FURTHER, THE SURFACE OF THE SEMICONDUCTOR CHIP 12, WHICH IS THE BONDING SURFACE SIDE THAT BONDS WITH THE SUBSTRATE 10, IS ALSO REFERRED TO AS THE SECOND SURFACE. THE SECOND SURFACE INCLUDES AT LEAST THE SURFACE OF THE SEMICONDUCTOR CHIP 12, BUT IS NOT LIMITED THERETO, AND MAY INCLUDE AT LEAST ONE SURFACE AMONG SURFACES OF VARIOUS FILMS (E.G., AN INSULATING FILM, A METAL FILM, ETC.) AND ELEMENTS PROVIDED ON THE CHIP SURFACE.

Specifically, for example, using a substrate processing apparatus 100 to be described later, the insulating film 16 is formed on at least the first surface, the second surface, and the surfaces of the micro bumps 14 of the substrate 10 and the semiconductor chip 12 bonded by the micro bumps 14, by an ALD (Atomic Layer Deposition) method or a CVD (Chemical Vapor Deposition) method through a substrate processing process to be described later. The thickness of the insulating film 16 formed in this step is 50 nm or less. Further, the insulating film 16 formed in this process is a film that can be formed at least on an insulating film, a metal film, or the like on the surface of the substrate 10 and the surface of the semiconductor chip 12. At this time, the insulating film 16 is formed at least on exposed surfaces into which an underfill material is to be filled, namely, the first surface of the substrate 10, which is the bonding surface side that bonds with the semiconductor chip 12, and the second surface of the semiconductor chip 12, which is the bonding surface side that bonds with the substrate 10.

### Underfill Film Formation Step, Step S2

Next, as illustrated in FIG. 1C, an underfill material is filled on the insulating film 16 between the substrate 10 and the semiconductor chip 12 bonded by the micro bumps 14, thereby forming an underfill film 18 (also referred to as filling with an underfill film). The underfill material is, for example, a resin. As the resin, for example, an epoxy resin or the like is used.

Accordingly, a semiconductor device 101 is formed in which the underfill film 18 is formed on a liner film including the insulating film 16 on the first surface, the second surface, and the surfaces of the micro bumps 14 between the substrate 10 and the semiconductor chip 12 bonded by the micro bumps 14.

Here, when the underfill material is filled between the substrate 10 and the semiconductor chip 12 in a state where the substrate 10 and the semiconductor chip 12 are bonded by the micro bumps 14, voids, which are filling defects, may occur. This is because the exposed surfaces into which the underfill material is to be filled—namely, the first surface of the substrate 10, the second surface of the semiconductor chip 12, and the surfaces of the micro bumps 14—include a plurality of different materials, thereby causing differences in wettability of the underfill material. This becomes more pronounced as the pitch between the substrate 10 and the semiconductor chip 12 to be filled with the underfill material becomes finer. In the present disclosure, before filling the underfill material, the insulating film 16 is formed as a liner film on the exposed surfaces into which the underfill material is to be filled. As a result, the material exposed on the surface to be filled with the underfill material becomes a single type of the insulating film 16, thereby making it possible to prevent differences in wettability among the surfaces of the substrate 10, the semiconductor chip 12, and the micro bumps 14, and to suppress the occurrence of voids during filling of the underfill material. Consequently, the strength, heat dissipation, and the like of the semiconductor device 101 can be enhanced, an increase in electrical resistance can be suppressed, and durability and electrical characteristics of the semiconductor device 101 can be improved.

Note that, prior to the liner film formation step S1 described above, a step of bonding the semiconductor chip 12 onto the substrate 10 by the micro bumps 14 respectively formed on the first surface of the substrate 10, which is the bonding surface side that bonds with the semiconductor chip 12, and on the second surface of the semiconductor chip 12, which is the bonding surface side that bonds with the substrate, may be provided.

### 2. Configuration of Substrate Processing Apparatus

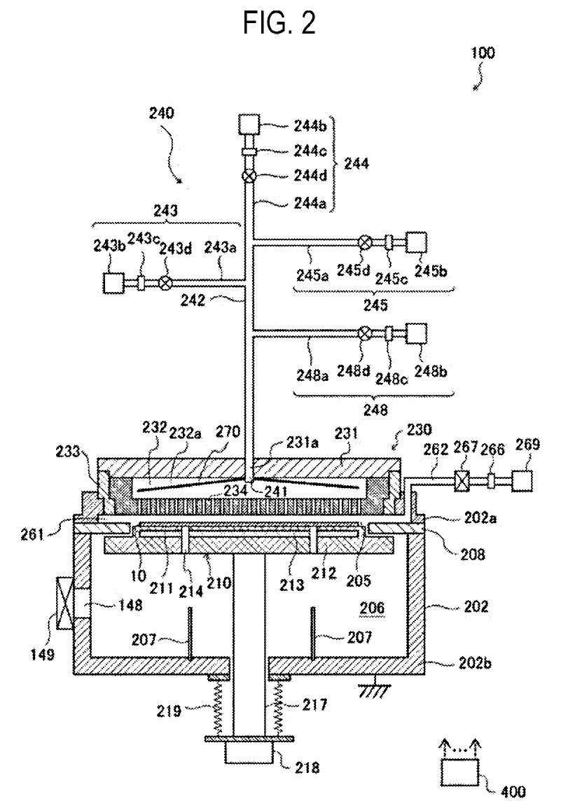

FIG. 2 is a configuration diagram illustrating an example of the substrate processing apparatus 100 used in the liner film formation step S1 described above. In the substrate processing apparatus 100, processing is performed on the substrate 10 to which the semiconductor chip 12 is bonded by the micro bumps 14 as illustrated in FIG. 1A. Therefore, in the following description, the substrate 10 means the substrate 10 to which the semiconductor chip 12 is bonded by the micro bumps 14.

The substrate processing apparatus 100 includes a vessel 202. A processing space 205 in which the substrate 10 is processed and a transfer space 206 through which the substrate 10 passes when being transferred to the processing space 205 are formed inside the vessel 202. The vessel 202 is composed of an upper vessel 202a and a lower vessel 202b. A partition plate 208 is provided between the upper vessel 202a and the lower vessel 202b. A structure defining the processing space 205 is referred to as a processing chamber 201.

A substrate loading/unloading port 148 adjacent to a gate valve 149 is provided on a side surface of the lower vessel 202b, and the substrate 10 moves between the vessel 202 and a transfer chamber (not illustrated) through the substrate loading/unloading port 148. A plurality of lift pins 207 are provided at the bottom of the lower vessel 202b. Further, the lower vessel 202b is grounded.

A substrate support 210 that supports the substrate 10 is disposed in the processing space 205. The substrate support 210 mainly includes a substrate mounting surface 211 on which the substrate 10 is placed, a substrate mounting table 212 including the substrate mounting surface 211 on its surface, and a heater 213 as a heating part provided inside the substrate mounting table 212. The substrate mounting table 212 is provided with through-holes 214 at positions corresponding to the lift pins 207, through which the lift pins 207 pass.

The substrate mounting table 212 is supported by a shaft 217. The shaft 217 penetrates the bottom of the vessel 202 and is connected to an elevator 218 outside the vessel 202.

By operating the elevator 218 to raise or lower the shaft 217 and the substrate mounting table 212, the substrate mounting table 212 is configured to be capable of raising and lowering the substrate 10 placed on the substrate mounting surface 211. The periphery of the lower end portion of the shaft 217 is covered with a bellows 219, thereby maintaining the processing space 205 airtight.

During transfer of the substrate 10, the substrate mounting table 212 descends such that the substrate mounting surface 211 reaches a position facing the substrate loading/unloading port 148, and during processing of the substrate 10, as illustrated in FIG. 2, the substrate mounting table 212 rises until the substrate 10 reaches a processing position inside the processing space 205.

A shower head 230 as a gas distribution mechanism is provided at an upper portion (upstream side) of the processing space 205. A through-hole 231a is formed in a lid 231 of the shower head 230. The through-hole 231a is in fluid communication with a common gas supply pipe 242 to be described later. A buffer chamber 232a including a buffer space 232 inside is provided in the shower head 230. The shower head 230 is configured to supply gas to the processing space 205 via the buffer space 232.

A flow straightening plate 270 is provided in the buffer space 232. The flow straightening plate 270 has a conical shape whose diameter increases toward a radial direction of the substrate 10 with a gas inlet 241 as a center. A lower end of an edge of the flow straightening plate 270 is configured to be positioned outside an outer periphery of an end portion of the substrate 10. The flow straightening plate 270 is configured to efficiently move the supplied gas toward a dispersion plate 234 to be described later.

The upper vessel 202a includes a flange, and a support block 233 is placed on and fixed to the flange. The dispersion plate 234 including a plurality of gas supply holes is placed on and fixed to the support block 233. Further, the lid 231 is fixed to an upper surface of the support block 233.

Next, a gas supply system 240 as a gas supply part will be described. A first gas supply pipe 243a, a second gas supply pipe 244a, a third gas supply pipe 245a, and a fourth gas supply pipe 248a are connected to the common gas supply pipe 242.

The first gas supply pipe 243a is provided, in order from an upstream side, with a first gas source 243b, a mass flow controller (MFC) 243c as a flow rate controller (flow rate control part), and a valve 243d as an opening/closing valve.

The first gas source 243b is a source of a precursor gas. The precursor gas is one of processing gases.

A first gas supply system 243 (also referred to as a precursor gas supply system or a silicon-containing gas supply system) mainly includes the first gas supply pipe 243a, the MFC 243c, and the valve 243d. The first gas supply system 243 may include the first gas source 243b.

The second gas supply pipe 244a is provided, in order from an upstream side, with a second gas source 244b, an MFC 244c, and a valve 244d.

The second gas source 244b is a source of a reaction gas that reacts with the precursor gas. The reaction gas is one of the processing gases.

A second gas supply system 244 (also referred to as a reaction gas supply system, an oxidizing gas supply system, or an oxygen-containing gas supply system) mainly includes the second gas supply pipe 244a, the MFC 244c, and the valve 244d. The second gas supply system 244 may include the second gas source 244b.

The third gas supply pipe 245a is provided, in order from an upstream side, with a third gas source 245b, an MFC 245c, and a valve 245d.

The third gas source 245b is a source of a reducing gas. The reducing gas is one of the processing gases.

A third gas supply system 245 (also referred to as a reducing gas supply system) mainly includes the third gas supply pipe 245a, the MFC 245c, and the valve 245d. The third gas supply system 245 may include the third gas source 245b.

The fourth gas supply pipe 248a is provided, in order from an upstream side, with a fourth gas source 248b, an MFC 248c, and a valve 248d.

The fourth gas source 248b is a source of an inert gas.

A fourth gas supply system 248 (also referred to as an inert gas supply system) mainly includes the fourth gas supply pipe 248a, the MFC 248c, and the valve 248d. The fourth gas supply system 248 may include the fourth gas source 248b.

The inert gas supplied from the fourth gas source 248b acts, in the substrate processing process, as a purge gas for purging gas remaining in the vessel 202 and the shower head 230.

An exhaust pipe 262 communicates with the processing space 205 via an exhaust buffer structure 261. The exhaust buffer structure 261 is provided circumferentially so as to surround an outer periphery of the substrate 10. In this embodiment, the exhaust buffer structure 261 is disposed between the partition plate 208 and the upper vessel 202a.

The exhaust pipe 262 is connected to the upper vessel 202a at an upper side of the exhaust buffer structure 261 so as to communicate with the processing space 205 via the exhaust buffer structure 261. The exhaust pipe 262 is provided with an APC (Auto Pressure Controller) 266 as a pressure controller for controlling the pressure inside the processing space 205 to a predetermined pressure. The APC 266 includes an adjustable valve body (not illustrated), and adjusts the conductance of the exhaust pipe 262 in accordance with an instruction from a controller 400 to be described later.

A valve 267 is provided on an upstream side of the APC 266 in the exhaust pipe 262. Further, a vacuum pump 269 is provided downstream of the exhaust pipe 262. The vacuum pump 269 exhausts the atmosphere in the processing space 205 through the exhaust pipe 262. The exhaust pipe 262, the valve 267, and the APC 266 are collectively referred to as an exhaust system. The exhaust system may include the vacuum pump 269.

### 3. Control Configuration

Next, the controller 400 will be described as a control part (control means) that controls operations of respective parts of the substrate processing apparatus 100.

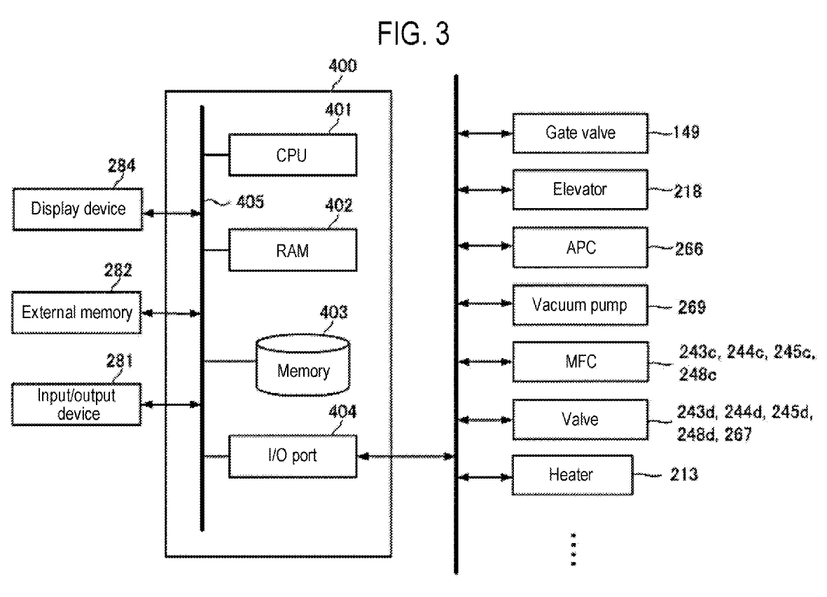

An outline of the controller 400 is illustrated in FIG. 3. The controller 400 is configured as a computer including a CPU (Central Processing Unit) 401, a RAM (Random Access Memory) 402, a memory 403 as a storage part, and an I/O port 404. The RAM 402, the memory 403, and the I/O port 404 are configured to be capable of exchanging data with the CPU 401 via an internal bus 405.

An input/output device 281 configured as, for example, a keyboard and an external memory 282 are configured to be connectable to the controller 400.

A display device 284 displays data and the like detected by respective monitor parts. In this embodiment, the input/output device 281 and the display device 284 are described as separate components; however, the present disclosure is not limited thereto. For example, if the input/output device also serves as a display screen such as a touch panel, the input/output device 281 and the display device 284 may be a single component.

The memory 403 is composed of, for example, a flash memory, an HDD (Hard Disk Drive), or the like. Process recipes describing procedures and conditions of substrate processing to be described later, recipe programs as control programs for controlling operations of the substrate processing apparatus to implement the process recipes, tables, and the like are readably stored in the memory 403. The recipe programs are combinations arranged such that respective procedures in the substrate processing process to be described later are executed by the controller 400 to obtain predetermined results, and function as programs. Hereinafter, such recipe programs, control programs, and the like are collectively referred to simply as "programs." Note that, when the term "program" is used herein, it may include only a process recipe, only a control program, or both. The RAM 402 is configured as a memory area (work area) in which programs, data, and the like read by the CPU 401 are temporarily stored.

The I/O port 404 is connected to respective components of the substrate processing apparatus 100 such as the gate valve 149, the elevator 218, the APC 266, the vacuum pump 269, the MFCs 243c, 244c, 245c, and 248c, the valves 243d, 244d, 245d, 248d, and 267, the heater 213, and the like.

The CPU 401 is configured to read and execute the control program from the memory 403, and to read a recipe program from the memory 403 in response to, for example, input of an operation command from the input/output device 281. The CPU 401 is configured to be capable of controlling, in accordance with the contents of the read recipe program, opening/closing operation of the gate valve 149, raising/lowering operation of the elevator 218, opening/closing operation of the APC 266, on/off control of the vacuum pump 269, flow rate adjustment operation of the MFCs 243c, 244c, 245c, and 248c, opening/closing operation of the valves 243d, 244d, 245d, 248d, and 267, temperature control of the heater 213, and the like.

The controller 400 according to this embodiment can be configured by installing a program in a computer using the external memory 282 (e.g., a magnetic disk such as a hard disk, an optical disc such as a DVD, a magneto-optical disc such as an MO, a semiconductor memory such as a USB memory, etc.) storing the above program. The means for supplying the program to the computer is not limited to supply the program via the external memory 282. For example, the program may be supplied by using a communication means such as the Internet or a dedicated line without using the external memory 282. The memory 403 and the external memory 282 are configured as computer-readable recording media in which programs are recorded. Hereinafter, these are collectively referred to simply as "recording media." Note that, when the term "recording media" is used herein, it may include only the memory 403, only the external memory 282, or both.

### 4. Substrate Processing Process

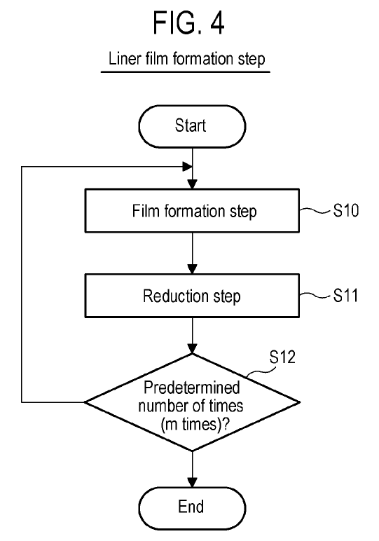

Next, as one step of a semiconductor manufacturing process, a step of forming the insulating film 16 in the liner film formation step S1 described above, using the substrate processing apparatus 100 described above, will be described in detail with reference to FIG. 4. In the following description, operations of respective parts constituting the substrate processing apparatus 100 are controlled by the controller 400. Also, in the following description, the substrate 10 means the substrate 10 to which the semiconductor chip 12 is bonded by the micro bumps 14.

It should be noted that, in this specification, when the term "substrate" is used, it may refer to either "the substrate itself" or "a stacked body (assembly) including the substrate and one or more predetermined layers, films, or the like formed on a surface thereof" (that is, the term "substrate" may include the predetermined layers, films, or the like formed on the surface). Further, in this specification, when the term "surface of the substrate" is used, it may refer to either "a surface (exposed surface) of the substrate itself" or "a surface of a predetermined layer, film, or the like formed on the substrate, that is, the outermost surface of the substrate as a stacked body."

Accordingly, in this specification, when it is stated that "a predetermined gas is supplied to a substrate," it may mean that "the predetermined gas is directly supplied to a surface (exposed surface) of the substrate itself", or that "the predetermined gas is supplied to a layer, film, or the like formed on the substrate, that is, to the outermost surface of the substrate as a stacked body." Further, in this specification, when it is stated that "a predetermined layer (or film) is formed on a substrate," it may mean that "the predetermined layer (or film) is directly formed on a surface (exposed surface) of the substrate itself", or that "the predetermined layer (or film) is formed on a layer, film, or the like formed on the substrate, that is, on the outermost surface of the substrate as a stacked body."

It should be noted that, in this specification, when the term "wafer" is used, it has the same meaning as the term "substrate." In such a case, the above description should be understood with "substrate" replaced by "wafer."

### Substrate Loading/Placing Step

By lowering the substrate mounting table 212 to a transfer position, the lift pins 207 are caused to pass through the through-holes 214 of the substrate mounting table 212. As a result, the lift pins 207 protrude by a predetermined height from the surface of the substrate mounting table 212. Next, the gate valve 149 is opened, and the substrate 10 is loaded into the processing chamber using a substrate transfer mechanism and is transferred onto the lift pins 207. Accordingly, the substrate 10 is supported in a horizontal posture on the lift pins 207 protruding from the surface of the substrate mounting table 212.

After the substrate 10 is loaded into the vessel 202, the substrate transfer mechanism is retracted outside the vessel 202, and the gate valve 149 is closed to seal the vessel 202. Thereafter, the substrate mounting table 212 is raised so that the substrate 10 is placed on the substrate mounting surface 211 provided on the substrate mounting table 212.

When the substrate 10 is loaded into the vessel 202, it is preferable to exhaust the interior of the vessel 202 by the exhaust system while supplying an inert gas into the vessel 202 from the fourth gas supply system 248. That is, it is preferable to supply the inert gas into the vessel 202 by opening at least the valve 248d of the fourth gas supply system 248 while exhausting the interior of the vessel 202 by operating the vacuum pump 269 and opening the APC 266. Further, the vacuum pump 269 is kept in operation at least from the substrate loading/placing step until a substrate unloading step to be described later is completed.

### Film Formation Step, S10

### Precursor Gas Supply, S101

When the substrate mounting table 212 is moved to a substrate processing position, the atmosphere is exhausted from the processing chamber 201 through the exhaust pipe 262 to adjust the pressure inside the processing chamber 201.

While adjusting the pressure at a predetermined pressure, when the temperature of the substrate 10 reaches, for example, a predetermined temperature of 200 degrees C or lower, the valve 243d is opened to start supplying a precursor gas into the processing space 205 through the common gas supply pipe 242 and the shower head 230. At this time, the MFC 243c is adjusted such that the flow rate of the precursor gas becomes a predetermined flow rate. At this time, the atmosphere is exhausted through the exhaust pipe 262. The supplied precursor gas forms a first layer on the surface of the substrate 10. After a predetermined time has elapsed from the start of supplying the precursor gas, the valve 243d is closed to stop supplying the precursor gas.

Next, the valve 248d is opened to supply an inert gas into the processing space 205 through the common gas supply pipe 242 and the shower head 230, thereby purging the processing space 205.

Here, the precursor gas is, for example, a silicon (Si)-containing gas containing silicon (Si). Specifically, as the Si-containing gas, for example, tetraethoxysilane (Si(OC₂H₅)₄, abbreviation: TEOS) gas, monosilane (SiH₄) gas, dichlorosilane (SiH₂Cl₂, abbreviation: DCS) gas, hexachlorodisilane (Si₂Cl₆, abbreviation: HCDS) gas, and the like are used. One or more of these may be used as the Si-containing gas.

By supplying, for example, a Si-containing gas to the substrate 10, a Si-containing layer is formed as the first layer on the surface of the substrate 10, that is, on at least the first surface, the second surface, and the surfaces of the micro bumps 14.

As the inert gas, for example, nitrogen (N₂) gas, argon (Ar) gas, helium (He) gas, neon (Ne) gas, xenon (Xe) gas, or other rare gases may be used. One or more of these may be used as the inert gas. The same applies to each step to be described later.

### REACTION GAS SUPPLY, S102

Next, the valve 244d is opened to start supplying a reaction gas into the processing space 205 through the common gas supply pipe 242 and the shower head 230. At this time, the MFC 244c is adjusted such that the flow rate of the reaction gas becomes a predetermined flow rate. The supplied reaction gas reacts with the first layer on the substrate 10, thereby forming a second layer on the substrate 10.

After forming the second layer on the substrate 10, the valve 244d is closed to stop supplying the reaction gas into the processing vessel.

Next, the valve 248d is opened to supply an inert gas into the processing space 205 through the common gas supply pipe 242 and the shower head 230, thereby purging the processing space 205.

Here, the reaction gas is, for example, an oxygen (O)-containing gas containing oxygen (also referred to as an oxidizing gas). Examples of the O-containing gas include oxygen (O₂) gas, ozone (O₃) gas, O₂ gas + hydrogen (H₂) gas, water vapor (H₂O gas), hydrogen peroxide (H₂O₂) gas, nitrous oxide (N₂O) gas, nitric oxide (NO) gas, nitrogen dioxide (NO₂) gas, carbon monoxide (CO) gas, carbon dioxide (CO₂) gas, and the like. One or more of these may be used as the O-containing gas.

By supplying, for example, the O-containing gas to the substrate 10, the Si-containing layer on the substrate 10 is oxidized, thereby forming a silicon oxide layer (SiO layer) on the substrate 10. That is, an SiO layer is formed on the surfaces of the substrate 10, the semiconductor chip 12, and the micro bumps 14.

### PERFORMING PREDETERMINED NUMBER OF TIMES

By performing a cycle a predetermined number of times (n times, where n is an integer of 1 or more), the cycle including the above steps S101 and S102, for example, a silicon oxide film (SiO film) is formed as a liner film including the insulating film 16 with a desired thickness on the surface of the substrate 10, that is, on at least the first surface, the second surface, and the surfaces of the micro bumps 14. The thickness of the insulating film 16 formed in this step is, for example, 50 nm or less.

In the film formation step S10 described above, a case in which an SiO film is formed as the insulating film 16 is described by way of example; however, the present disclosure is not limited thereto. For example, a supply system for an N-containing gas (also referred to as a nitriding gas) containing nitrogen (N) may be additionally provided to form the insulating film 16 such as a silicon oxynitride film (SiON film).

Further, in the film formation step S10 described above, a case in which the precursor gas and the reaction gas are supplied cyclically is described by way of example; however, the precursor gas and the reaction gas may be supplied simultaneously, or the insulating film 16 may be formed by supplying only the precursor gas without using the reaction gas.

### REDUCTION STEP, S11

Next, the valve 245d is opened to start supplying a reducing gas into the processing space 205 through the common gas supply pipe 242 and the shower head 230. At this time, the MFC 245c is adjusted such that the flow rate of the reducing gas becomes a predetermined flow rate. At this time, the atmosphere is exhausted through the exhaust pipe 262. The supplied reducing gas exposes the substrate 10 on which the insulating film 16 is formed to a reducing atmosphere. After a predetermined time has elapsed from the start of supplying the reducing gas, the valve 245d is closed to stop supplying the reducing gas.

Next, the valve 248d is opened to supply an inert gas into the processing space 205 through the common gas supply pipe 242 and the shower head 230, thereby purging the processing space 205.

Here, the reducing gas is, for example, an H-containing gas containing hydrogen (H). As the H-containing gas, for example, hydrogen (H₂) gas or the like is used.

### PERFORMING PREDETERMINED NUMBER OF TIMES, S12

A cycle including steps S10 and S11 is performed a predetermined number of times (m times, where m is an integer of 1 or more), at least once. Thus, the insulating film 16 can be formed as a liner film on at least the first surface, the second surface, and the surfaces of the micro bumps 14 of the substrate 10 and the semiconductor chip 12 bonded by the micro bumps 14 while suppressing oxidation of the micro bumps 14.

As described above, the insulating film 16 is formed as a liner film on at least the first surface, the second surface, and the surfaces of the micro bumps 14 of the substrate 10 and the semiconductor chip 12 bonded by the micro bumps 14, by an ALD method or a CVD method.

### SUBSTRATE UNLOADING STEP

The substrate mounting table 212 is lowered to support the substrate 10 on the lift pins 207 protruding from the surface of the substrate mounting table 212. Thereafter, the gate valve 149 is opened, and the substrate 10 is unloaded from the vessel 202 using the substrate transfer mechanism.

### 5. OTHER EMBODIMENTS

Next, other embodiments of the process of manufacturing the semiconductor device 101 described above will be described in detail. In the following embodiments, only differences from the above embodiment will be described in detail.

### SECOND EMBODIMENT

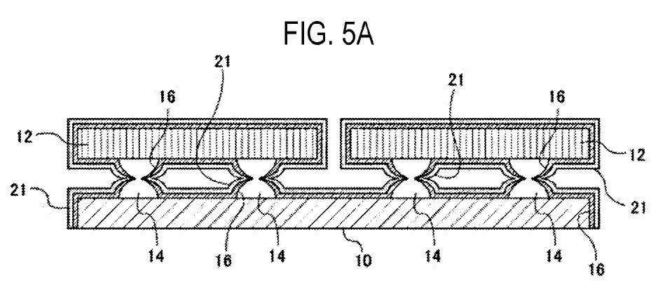

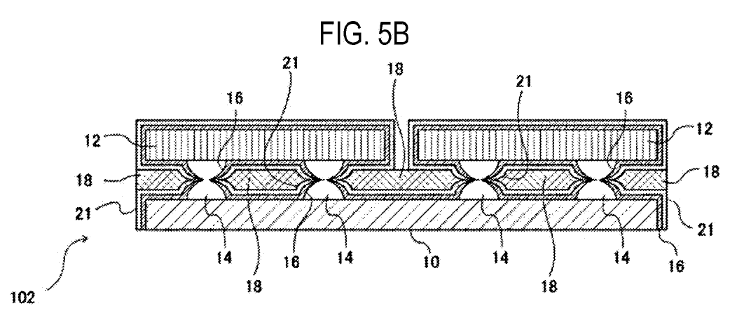

FIGS. 5A and 5B are diagrams illustrating a process of manufacturing a semiconductor device 102 in a second embodiment. In the second embodiment, after forming the insulating film 16 in step S1 described above, the following steps are performed. Hereinafter, differences will be mainly described, and descriptions of the same configurations as those in the above embodiment will be omitted.

### METAL FILM FORMATION STEP, S21

As illustrated in FIG. 5A, a metal film 21 is formed on the insulating film 16 formed on at least the first surface, the second surface, and the surfaces of the micro bumps 14 of the substrate 10 and the semiconductor chip 12 bonded by the micro bumps 14. The metal film 21 is formed, for example, by providing, in the substrate processing apparatus 100 described above, a metal-containing precursor gas supply system for supplying a metal-containing precursor gas containing a metal element, and supplying the metal-containing precursor gas. That is, as a liner film, the insulating film 16 and the metal film 21 are conformally formed in this order. At this time, the metal film 21 is formed at least on exposed surfaces into which an underfill material is to be filled, namely, the first surface of the substrate 10 on the bonding surface side with the semiconductor chip 12, the second surface of the semiconductor chip 12 on the bonding surface side with the substrate 10, and the surfaces of the micro bumps 14.

### UNDERFILL FILM FORMATION STEP, S22

Next, as illustrated in FIG. 5B, an underfill material is filled on the metal film 21 between the substrate 10 and the semiconductor chip 12 bonded by the micro bumps 14, thereby forming an underfill film 18.

Accordingly, a semiconductor device 102 is formed in which the underfill film 18 is formed on a liner film including the insulating film 16 and the metal film 21 between the substrate 10 and the semiconductor chip 12 bonded by the micro bumps 14.

In this embodiment as well, the same effects as those of the above embodiment can be achieved. That is, since the exposed surfaces into which the underfill material is to be filled are a single type of the metal film 21, it is possible to prevent differences in wettability on the surface, and to suppress the occurrence of voids during filling of the underfill material. In this embodiment, by forming the metal film 21 with high thermal emissivity between the insulating film 16 and the underfill film 18 on the insulating film 16 on the surfaces of the substrate 10 and the semiconductor chip 12, heat accumulation during operation of the semiconductor device 102 is suppressed, thereby enabling high-voltage operation and improving operating speed.

### THIRD EMBODIMENT

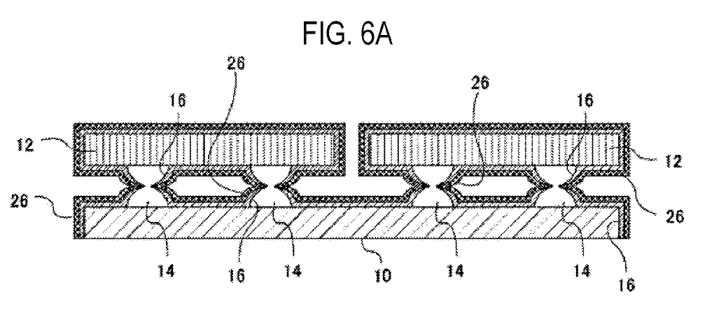

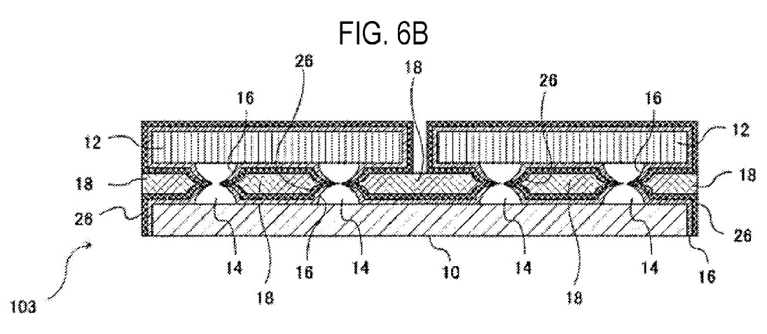

FIGS. 6A and 6B are diagrams illustrating a process of manufacturing a semiconductor device 103 in a third embodiment. In the third embodiment, after forming the insulating film 16 in step S1 described above, the following steps are performed.

### ORGANIC-GROUP-CONTAINING INSULATING FILM FORMATION STEP, S31

As illustrated in FIG. 6A, an organic-group-containing insulating film 26 including an alkyl group is formed on the insulating film 16 formed on at least the first surface, the second surface, and the surfaces of the micro bumps 14 of the substrate 10 and the semiconductor chip 12 bonded by the micro bumps 14. The organic-group-containing insulating film 26 is formed, for example, by providing, in the substrate processing apparatus 100 described above, an organic-group-containing precursor gas supply system containing an organic-group-containing precursor including an alkyl group, and supplying an organic-group-containing precursor gas. That is, as a liner film, the insulating film 16 and the organic-group-containing insulating film 26 are conformally formed in this order. That is, a film that is in contact with the underfill film 18 of an uppermost layer of the liner film is the organic-group-containing insulating film 26. At this time, the organic-group-containing insulating film 26 is formed at least on exposed surfaces into which an underfill material is to be filled, namely, the first surface of the substrate 10 on the bonding surface side with the semiconductor chip 12, the second surface of the semiconductor chip 12 on the bonding surface side with the substrate 10, and the surfaces of the micro bumps 14.

### UNDERFILL FILM FORMATION STEP, S32

Next, as illustrated in FIG. 6B, an underfill material is filled on the organic-group-containing insulating film 26 between the substrate 10 and the semiconductor chip 12 bonded by the micro bumps 14, thereby forming the underfill film 18.

Accordingly, a semiconductor device 103 is formed in which the underfill film 18 is formed on a liner film including the insulating film 16 and the organic-group-containing insulating film 26 between the substrate 10 and the semiconductor chip 12 bonded by the micro bumps 14.

In this embodiment as well, the same effects as those of the above embodiments can be achieved. That is, since the exposed surfaces into which the underfill material is to be filled are a single type of the organic-group-containing insulating film 26, it is possible to prevent differences in wettability on the surface, and to suppress the occurrence of voids during filling of the underfill material. In this embodiment, by forming the organic-group-containing insulating film 26 with high water repellency and high wettability on the exposed surfaces into which the underfill material is to be filled, the occurrence of voids during filling of the underfill material can be further suppressed.

### FOURTH EMBODIMENT

Further, the metal film formation step S21 in the second embodiment described above is performed between the step of forming the insulating film 16 in step S1 and the step of forming the organic-group-containing insulating film 26 in step S31 in the third embodiment described above. That is, as a liner film, the insulating film 16, the metal film 21, and the organic-group-containing insulating film 26 are conformally formed in this order. That is, a film that is in contact with the underfill film 18 of an uppermost layer of the liner film is the organic-group-containing insulating film 26.

Accordingly, a semiconductor device 104 is formed in which the underfill film 18 is formed on a liner film including the insulating film 16, the metal film 21, and the organic-group-containing insulating film 26 between the substrate 10 and the semiconductor chip 12 bonded by the micro bumps 14.

In this embodiment as well, the same effects as those of the above embodiments can be achieved. That is, since the exposed surfaces into which the underfill material is to be filled are a single type of the organic-group-containing insulating film 26, it is possible to prevent differences in wettability on the surface, and to suppress the occurrence of voids during filling of the underfill material. Further, in this embodiment, by forming the organic-group-containing insulating film 26 with high water repellency and high wettability on the exposed surfaces into which the underfill material is to be filled, the occurrence of voids during filling of the underfill material can be further suppressed. Further, by providing the metal film 21 between the insulating film 16 and the organic-group-containing insulating film 26, heat accumulation during operation of the semiconductor device 104 can be suppressed, thereby enabling high-voltage operation and improving operating speed.

### FIFTH EMBODIMENT

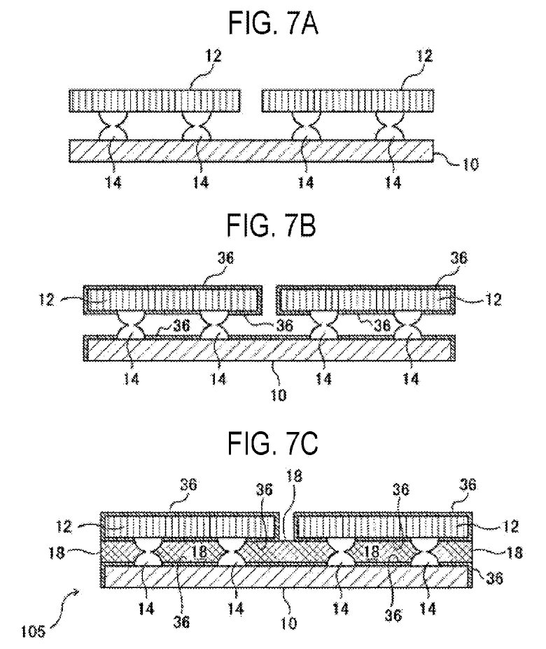

FIGS. 7A to 7C are diagrams illustrating a process of manufacturing a semiconductor device 105 in a fifth embodiment.

### INSULATING FILM FORMATION STEP, S51

On at least the first surface and the second surface of the substrate 10 and the semiconductor chip 12 bonded by the micro bumps 14 as illustrated in FIG. 7A, a film including, as a lowermost layer, an insulating film 36, of which deposition on the micro bumps 14 is inhibited, is formed as a liner film as illustrated in FIG. 7B. The thickness of the insulating film 36 formed in this step is, for example, 50 nm or less. That is, the insulating film 36 is not formed on the surfaces of the micro bumps 14 and is selectively formed at least on the first surface of the substrate 10 on the bonding surface side with the semiconductor chip 12 and on the second surface of the semiconductor chip 12 on the bonding surface side with the substrate 10.

### UNDERFILL FILM FORMATION STEP, S52

Next, as illustrated in FIG. 7C, an underfill material is filled on the insulating film 36 between the substrate 10 and the semiconductor chip 12 bonded by the micro bumps 14, thereby forming an underfill film 18.

Accordingly, a semiconductor device 105 is formed in which the underfill film 18 is formed on a liner film including the insulating film 36 between the substrate 10 and the semiconductor chip 12 bonded by the micro bumps 14.

In this embodiment as well, the same effects as those of the above embodiments can be achieved. That is, since the exposed surfaces into which the underfill material is to be filled are a single type of the insulating film 36, it is possible to prevent differences in wettability on the surface, and to suppress the occurrence of voids during filling of the underfill material. Further, in this embodiment, as compared with a case where the underfill material is filled on the conformally formed insulating film 16, a space for filling the underfill material becomes wider, thereby facilitating filling of the underfill material. In this embodiment, since the insulating film 36 is selectively formed on the surface of the substrate 10 on the bonding surface side with the semiconductor chip 12 and on the surface of the semiconductor chip 12 on the bonding surface side with the substrate 10, an aspect ratio of the space to be filled with the underfill material becomes lower than that of the insulating film 16 conformally formed between the substrate 10 and the semiconductor chip 12.

As described above, the underfill film 18 is formed on a liner film including at least one layer of the insulating film 16 (or the insulating film 36) between the substrate 10 and the semiconductor chip 12 bonded by the micro bumps 14. Since a base material of the exposed surfaces into which the underfill material is to be filled is a single type of film, it is possible to prevent differences in wettability of the underfill material among materials, and to suppress the occurrence of voids during filling of the underfill material. Further, by forming the liner film in multiple layers, it is possible to combine film types that are excellent in adhesion to the substrate 10, the semiconductor chip 12, or the micro bumps 14, pressure resistance, and wettability for the underfill material.

### OTHER EMBODIMENTS

Although the respective embodiments are described above in detail, the present disclosure is not limited to the above-described embodiments, and various modifications and changes can be made without departing from the spirit and scope of the present disclosure.

That is, in the above-described embodiments, an example is described in which a liner film including at least one layer of insulating film is formed; however, the present disclosure is not particularly limited with respect to the type of film or combinations of film types.

Further, in the above-described embodiments, an example is described in which a film is processed using a single-wafer type substrate processing apparatus that processes one or several substrates at a time. The present disclosure is not limited to the above-described embodiments, and is also suitably applicable to a case where a film is processed using a batch-type substrate processing apparatus that processes a plurality of substrates at a time. Further, in the above-described embodiments, an example is described in which a film is processed using a substrate processing apparatus including a cold-wall type processing furnace. The present disclosure is not limited to the above-described embodiments, and is also suitably applicable to a case where a film is processed using a substrate processing apparatus including a hot-wall type processing furnace.

Even in a case where these substrate processing apparatuses are used, the respective processes can be performed with the same processing procedures and processing conditions as those in the above-described embodiments and other embodiments, and the same effects as those in the above embodiments and other embodiments can be achieved.

Further, it is preferable that recipes used for the respective processes are prepared individually according to the process contents and are stored in the memory 403 via a telecommunication line or the external memory 282. When starting each process, it is preferable that the CPU 401 appropriately selects an appropriate recipe according to the process contents from among a plurality of recipes stored in the memory 403. Thus, various types of films with different film types, composition ratios, film qualities, and film thicknesses can be formed with high reproducibility by a single substrate processing apparatus. Further, an operator's burden can be reduced, and each process can be started promptly while avoiding operational errors.

Further, the above recipes are not limited to those newly created. For example, the recipes may be prepared by modifying existing recipes already installed in the substrate processing apparatus. When modifying a recipe, the modified recipe may be installed in the substrate processing apparatus via a telecommunication line or a recording medium storing the recipe. Alternatively, the existing recipes already installed in the substrate processing apparatus may be directly modified by operating the input/output device 281 included in the existing substrate processing apparatus.

The above-described embodiments can be used in appropriate combinations. In such a case, processing procedures and processing conditions may be, for example, the same as those of the above-described embodiments.

According to the present disclosure, it is possible to suppress the occurrence of voids when an underfill material is filled between a substrate and a semiconductor chip.

While certain embodiments are described, these embodiments are presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising: preparing the substrate bonded to a semiconductor chip by micro bumps formed on at least one of a first surface of the substrate, which is a bonding surface side that bonds with the semiconductor chip, and a second surface of the semiconductor chip, which is a bonding surface side that bonds with the substrate; and forming, on the first surface and the second surface, a liner film including an insulating film so as to form a surface on which an underfill film can be formed between the substrate and the semiconductor chip.

2. The method of claim 1, wherein the micro bumps are formed on the first surface and the second surface.

3. The method of claim 1, wherein the act of forming the liner film further includes forming the liner film on surfaces of the micro bumps.

4. The method of claim 1, further comprising: after the act of forming the liner film, forming the underfill film between the substrate and the semiconductor chip.

5. The method of claim 1, wherein the insulating film is composed of at least one layer of film.

6. The method of claim 1, wherein the insulating film is formed by an ALD method or a CVD method.

7. The method of claim 1, wherein the insulating film is formed so as not to cause a difference in wettability at least between the first surface and the second surface.

8. The method of claim 1, wherein the liner film includes a metal film formed on the insulating film.

9. The method of claim 8, wherein the metal film is formed so as not to cause a difference in wettability at least between the first surface and the second surface.

10. The method of claim 1, wherein the liner film includes an insulating film of which deposition on the micro bumps is inhibited.

11. The method of claim 1, wherein the liner film includes at least one layer of the insulating film, and an insulating film of which deposition on the micro bumps is inhibited is formed as a lowermost layer of the insulating film.

12. The method of claim 1, wherein a film of the liner film that is in contact with the underfill film is an organic-group-containing insulating film.

13. The method of claim 12, wherein the organic-group-containing insulating film includes an alkyl group.

14. The method of claim 12, wherein the organic-group-containing insulating film is formed so as not to cause a difference in wettability at least between the first surface and the second surface.

15. The method of claim 1, wherein the act of forming the liner film includes performing, at least once: forming the insulating film; and exposing the insulating film to a reducing atmosphere.

16. The method of claim 15, wherein the act of forming the liner film further includes, after forming the insulating film, supplying a metal-containing precursor gas to form a metal film.

17. A method of manufacturing a semiconductor device, comprising the method of claim 1.

18. A substrate processing apparatus configured to perform the method of claim 1.

19. A semiconductor device comprising: a substrate; a semiconductor chip; micro bumps formed on at least one of a first surface of the substrate, which is a bonding surface side that bonds with the semiconductor chip, and a second surface of the semiconductor chip, which is a bonding surface side that bonds with the substrate, the micro bumps connecting the substrate and the semiconductor chip; and a liner film including a surface on which an underfill film can be formed between the substrate and the semiconductor chip, the liner film including an insulating film formed on the first surface and the second surface.

20. A non-transitory computer-readable recording medium storing a program that causes, by a computer, a substrate processing apparatus to perform a process comprising: preparing a substrate bonded to a semiconductor chip by micro bumps formed on at least one of a first surface of the substrate, which is a bonding surface side that bonds with the semiconductor chip, and a second surface of the semiconductor chip, which is a bonding surface side that bonds with the substrate; and forming, on the first surface and the second surface, a liner film including an insulating film so as to form a surface on which an underfill film can be formed between the substrate and the semiconductor chip.
